(19) United States
(12) Patent Application Publication
(10) Pub. No.: US 2007/0196770 A1
(43) Pub. Date: Aug. 23, 2007

(54) Printing sleeve and method of manufacturing the same

(76) Inventor: David Recchia, Smyrna, GA (US)

Correspondence Address: John L. Cordani;Carmody & Torrance LLP, P.O. Box 1110, 50 Leavenworth Street, Waterbury, CT, 06721-1110, US

(21) Appl. No.: 11/360,064

(22) Filed: Feb. 22, 2006

(51) Int. Cl. G03F 7/00

(52) U.S. Cl. 430/302

(57) ABSTRACT

The present invention is directed to the manufacture of “seamless” photosensitive printing elements from substantially planar printing plate blanks wrapped around cylindrical printing sleeves or carriers. The method comprises the steps of cutting a photosensitive printing element to a size for wrapping around a printing sleeve, trimming ends of the photosensitive printing element to create a gap when the printing element is wrapped around the printing sleeve, attaching the photosensitive printing element to the printing sleeve and filling the gap between the ends of the photosensitive printing element with a filler material.

### FIELD OF THE INVENTION

The present invention is directed to the manufacture of “seamless” photosensitive printing elements from substantially planar printing plate blanks wrapped around cylindrical printing sleeves or carriers.

### BACKGROUND OF THE INVENTION

Flexography is a method of printing that is commonly used for high-volume runs. Flexographic printing plates are relief plates with image elements raised above open areas. Such plates offer a number of advantages to the printer, based chiefly on their durability and the ease with which they can be made. Flexography is employed for printing on a variety of substrates such as paper, paperboard stock, corrugated board, films, foils and laminates. Newspapers and grocery bags are prominent examples. Coarse surfaces and stretch films can be economically printed only by means of flexography.

Although flexographic printing elements are typically used in “flat” sheet form, which may then be mounted on a cylindrical carrier sleeve, there are particular applications and advantages to using the printing element in a continuous cylindrical form, or a “continuous in-the-round” (CITR) sleeve. CITR sleeves add the benefits of digital imaging, accurate registration, fast mounting, and no plate lift to the flexographic printing process. CITR sleeves have applications in the flexographic printing of continuous designs such as in wallpaper, decoration and gift-wrapping paper, and other continuous designs such as tablecloths, etc. CITR sleeves enable flexographic printing to be more competitive with gravure and offset on print quality.

A typical flexographic printing plate as delivered by its manufacturer, is a multilayered article made of, in order, a backing or support layer, one or more unexposed photosensitive or photocurable layers, a protective layer or slip film, and a cover sheet. A typical CITR photopolymer sleeve generally comprises a sleeve carrier (support layer) and at least one unexposed photocurable layer on top of the support layer. The photocurable layers typically contain binders, monomers, photoinitiators, and other performance additives. Photocurable compositions include those described in U.S. patent application Ser. No. 10/353,446 filed Jan. 29, 2003, the teachings of which are incorporated herein by reference in their entirety. Various photopolymers such as those based on polystyrene-isoprene-styrene, polystyrene-butadiene-styrene, polyurethanes and/or thiolenes as binders are useful. Preferable binders are polystyrene-isoprene-styrene, and polystyrene-butadiene-styrene, especially block co-polymers of the foregoing.

Flexographic printing element are produced from photocurable printing blanks by imaging the photocurable printing blank to produce the desired relief image on the surface of the printing element. This is generally accomplished by selectively exposing the photocurable material to actinic radiation, which exposure acts to harden or crosslink the photocurable material in the irradiated areas. The printing element is selectively exposed to actinic radiation in one of three related ways. In the first alternative, a photographic negative with transparent areas and substantially opaque areas is used to selectively block the transmission of actinic radiation to the printing plate element. In the second alternative, the photopolymer layer is coated with an actinic radiation (substantially) opaque layer that is sensitive to laser ablation. A laser is then used to ablate selected areas of the actinic radiation opaque layer creating an in situ negative. This technique is well-known in the art, and is described for example in U.S. Pat. Nos. 5,262,275 and 6,238,837 to Fan, and in U.S. Pat. No. 5,925,500 to Yang et al., the subject matter of each of which is herein incorporated by reference in its entirety. In the third alternative, a focused beam of actinic radiation is used to selectively expose the photopolymer. Any of these alternative methods is acceptable, with the criteria being the ability to selectively expose the photopolymer to actinic radiation thereby selectively curing portions of the photopolymer.

Next, the photopolymer layer of the printing element is developed to remove uncured (i.e., non-crosslinked) portions of the photopolymer, without disturbing the cured portions of the photopolymer layer, to produce the relief image. The development step has traditionally been accomplished in a variety of ways, including water washing, solvent washing, and thermal development (blotting). During thermal development, the heated printing element is contacted with an absorbent material that absorbs or otherwise removes the softened and/or melted uncured photopolymer. Thermal development has the advantage of not requiring an additional drying step after development and thus provides the ability to go more quickly from plate to press. The basic parameters of this process are described in U.S. Pat. Nos. 5,279,697, 5,175,072 and 3,264,103, in published U.S. patent publication Nos. US 2003/0180655, and U.S. 2003/0211423, and in WO 01/88615, WO 01/18604, and EP 1239329, the teachings of each of which are incorporated herein by reference in their entirety.

Upon completion of the developing process, the printing plate element may be post-exposed to further actinic radiation and/or subjected to detachification, cooled and is then ready for use.

When flexographic printing elements are manufactured from flat printing plates, there may be distortions in the printing plate as a result of it being wrapped around the rounded surface of a plate cylinder or printing sleeve. In addition, regardless of how tight the joint is between the two ends of the plate, a seam is always present. The ends are typically fixed to the cylinder or print sleeve by taping them to the cylinder or print sleeve, using double-sided adhesive tape. If printing plates consisting of individual parts are used, the edges of the individual parts abut at the respective connection points and are similarly fixed on the printing cylinder or print sleeve with double-sided adhesive tape.

Processes to connect the edges of photopolymerizable printing elements are known in the art. For example, a combined pressure and heat treatment may be used. However, this process requires a great deal of equipment, and also requires a subsequent smoothing step, as well as further post-treatment steps.

Other attempts have focused on sealing the gap between abutting edges by inserting filling materials such as adhesive cement or filling compositions based on rubber, polyacrylate or epoxy resins and the like. However, non-printing connection points are obtained whose strength and elastic properties are not adequate to withstand the forces acting on the photopolymer printing plate during printing and the connection points have a tendency to break open after relatively short periods of operation.

More recently, as discussed in U.S. Patent Application Publication No. 2004/0060647 to Tabora, the subject matter of which is herein incorporated by reference in its entirety, a process has been developed for micro-cutting edges of a photosensitive printing element to create an essentially seamless joint (or break) between the lead edge and trailing edge of the printing element that is then mounted on a printing cylinder. However, a visible seam is still apparent, which may interfere with print quality.

“Seamless” photosensitive elements can be made by the SEAMEX® process, which involves wrapping a layer of photocurable material to a nickel print sleeve having a heat-activated primer coat to bond with the material so that the ends of the plate are joined together. The entire assembly is placed in an oven to cure and bond the photocurable layer to the primer coat and melt the ends of the photopolymeric layer together. The photocurable layer on the sleeve is then ground to the necessary thickness, wiped clean and sprayed with a protective coating to prevent negatives from sticking to the photopolymer during exposure. The process of wrapping, curing and melting, grinding and spraying the photocurable layer to the sleeve can take up to two days to accomplish. Furthermore, the photocurable layer on the sleeve must still undergo the same steps of imaging, exposing, and developing to form the relief surface for printing.

Thus, there remains a need in the art for an improved process for providing an essentially seamless photosensitive printing element that can be made in an efficient manner and that reduces the time needed for heat curing and grinding and that eliminates the need for vacuum, as is now required by many of the processes of the prior art.

### SUMMARY OF THE INVENTION

It is an object of the present invention to provide a method of manufacturing an essentially seamless plate-on-sleeve that overcomes many of the deficiencies of the prior art.

It is another object of the present invention to provide a printing sleeve with a photosensitive layer mounted thereon that takes less time to produce as compared to printing sleeves of the prior art.

To that end, the present invention is directed to a method of manufacturing an essentially seamless flexographic printing element comprising the steps of:

a) cutting a photosensitive printing element to a size that is wrappable around a printing sleeve;

b) trimming ends of the photosensitive printing element to create a gap when the printing element is wrapped around the printing sleeve;

c) attaching the photosensitive printing element to the printing sleeve; and

d) filling the gap between the ends of the photosensitive printing element with a filler material,

wherein a seamless photosensitive printing element is formed on the printing sleeve.

The present invention is also directed to an apparatus for manufacturing an essentially seamless relief image printing sleeve comprising:

a) means for supporting a cylindrical printing sleeve;

b) means for cutting a photosensitive printing element to a size that is wrappable around the cylindrical printing sleeve;

c) means for trimming ends of the photosensitive printing element to create a gap when the photosensitive printing element is wrapped around the printing sleeve; and

d) means for filling the gap between the ends of the photosensitive printing element with a filler material;
wherein a seamless photosensitive printing element is formable on the printing sleeve.

### BRIEF DESCRIPTION OF THE FIGURES

FIG. 1 depicts one view of the “seamless” printing element of the present invention.

### DETAILED DESCRIPTION OF THE PREFERRED EMBODIMENTS

The present invention is directed to an improved method of turning a “plate on sleeve” into a seamless printing sleeve that overcomes many of the problems of the prior art.

In particular, the present invention is directed to a method of manufacturing a seamless flexographic printing element comprising the steps of:

a) cutting a photosensitive printing element to a size that is wrappable around a printing sleeve;

b) trimming ends of the photosensitive printing element to create a gap when the printing element is wrapped around the printing sleeve;

c) attaching the photosensitive printing element to the printing sleeve; and

d) filling the gap between the ends of the photosensitive printing element with a filler material,

wherein a seamless photosensitive printing element is formed on the printing sleeve.

The photosensitive printing element typically comprises one or more layers of photocurable material on a suitable support layer. The one or more layers of photosensitive material typically comprise binders, monomers, photoinitiators, and performance additives. The support layer may be polyethylene (PET) although other suitable support layers would also be well known to one skilled in the art. A removable coversheet may also be provided to protect the printing element from damage during transport and handling. If used, the removable coversheet is removed prior to mounting the photosensitive printing element on the printing sleeve.

The photosensitive printing element may also have an actinic radiation substantially opaque layer on top of the one or more layers of photosensitive printing element. If used, the actinic radiation opaque layer comprises carbon black, although other similar actinic radiation opaque materials may also be used.

Prior to being mounted on the printing sleeve, the photosensitive printing element is back exposed to actinic radiation to provide a hardened floor layer.

Next, the photosensitive printing element is cut to a size that fits on the printing sleeve and the leading and trailing ends of the photosensitive printing element are trimmed to create a gap between the two edges when the printing element is wrapped around the printing sleeve. While the ends may be at right angles to the layer surface, it is preferable that the edges be beveled or chamfered. In a preferred embodiment, the ends are beveled. The bevel cut is used to prevent a dead spot in the printing cylinder and to give support to exposed imaged in the photosensitive printing element. The ends of the photosensitive printing element can be beveled up to a depth of about 0.030 inches.

Thereafter, the photosensitive printing element is attached to the printing sleeve, typically by laminating the photosensitive printing element to the printing sleeve. The printing sleeve comprises a cylindrical sleeve layer, which has a backing layer mounted thereon. The purpose of the backing layer is to allow the removable mounting of the photosensitive printing element onto the printing sleeve. When the photosensitive printing element is laminated to the printing sleeve, the printing element contacts the backing layer. The printing sleeve is mounted on a printing cylinder.

The backing layer is typically selected from the group consisting of double-sided self-adhesive tape, foam cushioning, and transfer tape, although other backing layers may also be used and would be known to one skilled in the art. In a preferred embodiment, the backing layer is double-sided self-adhesive tape.

The cylindrical sleeve layer is typically selected from the group consisting of metal, plastics, glass-fiber reinforced plastic, and the like. In a preferred embodiment, the cylindrical sleeve layer is nickel.

Once the photosensitive printing element is laminated to the printing sleeve, the gap that has been created between the ends of the photosensitive printing element can be filled or injected to weld the seam together. The filler material preferably comprises a photosensitive composition that is the same as the composition that is used in the photosensitive printing element. The filler material is typically molten and is injected into the gap created between the two ends of the photosensitive printing element. Thereafter, the filler material hardens or solidifies to create a continuous photosensitive printing element.

The filler material may be injected into the gap using various means that precisely dispense or meter the required amount of material. In a preferred embodiment, the filler material is injected into the gap using a spool valve. Spool valves are described, for example, in U.S. Patent Application Publication No. 2004/0119182 to Kozman, the subject matter of which is herein incorporated by reference in its entirety.

Excess filler is then removed from the photosensitive printing element to provide a desired thickness of the photosensitive printing element. This step may be accomplished by squeegeeing off excess material or grinding the photosensitive printing element to the desired thickness. It is generally preferred that the thickness of the photosensitive printing element be about 0.030 inches to about 0.287 inches.

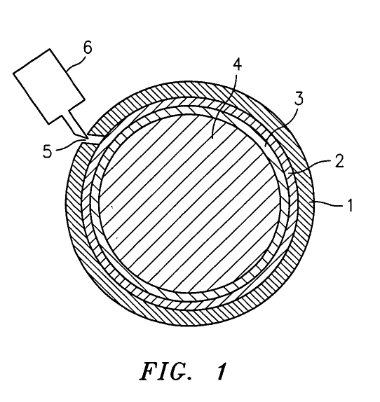

FIG. 1 depicts an example of a photosensitive printing element prepared in accordance with the present invention. As seen in FIG. 1, a photosensitive printing element 1 is wrapped around the outer surface of a cylindrical printing sleeve 3 having a backing layer 2 attached thereto. The printing sleeve 3 is mounted on a printing cylinder 4. As seen in FIG. 1, the leading edge and trailing edge of the photosensitive printing element 1 are beveled and a gap 5 is created between the leading edge and the trailing edge. A spool valve 6 is then used to fill the gap 5 with molten photopolymer of the same composition as is used in the photosensitive printing element.

Once the photosensitive printing element has been mounted on the printing sleeve, the printing element may be imaged and exposed to create the desired relief image. Thereafter, the imaged and exposed photosensitive printing element may be developed to remove uncured photopolymer remaining on the surface of the photosensitive printing element. While various means of development may be used, including water and solvent washing, it is typically preferable to accomplish the development step using thermal development.

The present invention is also directed to an apparatus for manufacturing the seamless relief image printing element of the invention comprising:

a) means for supporting a cylindrical printing sleeve;

b) means for cutting a photosensitive printing element to a size that is wrappable around the cylindrical printing sleeve;

c) means for trimming ends of the photosensitive printing element to create a gap when the photosensitive printing element is wrapped around the printing sleeve; and

d) means for filling the gap between the ends of the photosensitive printing element with a filler material;

wherein a seamless photosensitive printing element is formable on the printing sleeve.

As discussed above, the means for supporting the cylindrical printing sleeve is preferably a printing cylinder.

The means for cutting the photosensitive printing element to a size that is wrappable around the cylindrical printing sleeve and for trimming the ends of the photosensitive printing element to create a gap is typically one or more automatic cutting tables, although other cutting means are also usable in the practice of the invention and would be known to one skilled in the art.

The means for filling the gap preferably comprises a spool valve that is capable of injecting molten filler material into the gap between the ends of the photosensitive printing element.

It is to be understood that the following claims are intended to cover all of the generic and specific features of the invention described herein and all statements of the scope of the invention which as a matter of language might fall therebetween.

What is claimed is:

1. A method of manufacturing a flexographic printing element comprising the steps of:
a) cutting a photosensitive printing element to a size for wrapping around a printing sleeve;
b) trimming ends of the photosensitive printing element to create a gap when the printing element is wrapped around the printing sleeve;
c) attaching the photosensitive printing element to the printing sleeve; and
d) filling the gap between the ends of the photosensitive printing element with a filler material,
wherein a seamless photosensitive printing element is formed on the printing sleeve.

2. The method according to claim 1, wherein the step of trimming the photosensitive printing element comprises beveling the ends of the photosensitive printing element.

3. The method according to claim 2, wherein the ends of the photosensitive printing element are beveled up to a depth of about 0.030 inches.

4. The method according to claim 1, wherein the filler material comprises a photosensitive composition that is the same composition used in the photosensitive printing element.

5. The method according to claim 1, wherein the filler material is liquid or molten when it is injected into the gap, and thereafter solidifies.

6. The method according to claim 1, further comprising the step of removing excess filler material to provide a desired thickness of the photosensitive printing element.

7. The method according to claim 6, wherein the step of removing excess filler material comprises squeegeeing off excess material or grinding the photosensitive printing element to a desired thickness.

8. The method according to claim 6, wherein the filler material is injected into the gap using a spool valve.

9. The method according to claim 1, comprising the step of back-exposing the photosensitive printing element to actinic radiation prior to step a).

10. The method according to claim 1, wherein the step of attaching the photosensitive printing element to the printing sleeve comprises laminating the photosensitive printing element to the printing sleeve.

11. The method according to claim 1, wherein the printing sleeve comprises a cylindrical sleeve layer having a backing layer mounted thereon, and wherein when the printing element is attached to the printing sleeve, the printing element contacts with the backing layer.

12. The method according to claim 11, wherein the backing layer is selected from the group consisting of double-sided self-adhesive tape, foam cushioning, and transfer tape.

13. The method according to claim 12, wherein the backing layer is double-sided self-adhesive tape.

14. The method according to claim 11, wherein the cylindrical sleeve layer is selected from the group consisting of metal, plastics, glass-fiber reinforced plastic, and the like.

15. The method according to claim 14, wherein the cylindrical sleeve layer is nickel.

16. The method according to claim 1, wherein the photosensitive printing element is coated with an actinic radiation opaque layer.

17. The method according to claim 16, wherein the actinic radiation opaque layer comprises carbon black.

18. The method according to claim 1, comprising the steps of imaging and exposing the photosensitive printing element after the photosensitive printing element is mounted on the printing sleeve.

19. The method according to claim 18, further comprising the step of developing the imaged and exposed photosensitive printing element to remove uncured photopolymer.

20. The method according to claim 19, wherein the step of developing the photosensitive printing element is accomplished using thermal development.

21. The method according to claim 1, wherein the thickness of the photosensitive printing element is about 0.030 inches to about 0.287 inches.

22. The method according to claim 2, wherein the edges of the photosensitive printing element are beveled using an automatic cutting table.

23. The method according to claim 1, wherein the printing sleeve is mounted on a printing cylinder.

24. An apparatus for manufacturing a relief image printing element comprising:
a) means for supporting a cylindrical printing sleeve;
b) means for cutting a photosensitive printing element to a size that is wrappable around the cylindrical printing sleeve;
c) means for trimming ends of the photosensitive printing element to create a gap when the photosensitive printing element is wrapped around the printing sleeve; and
d) means for filling the gap between the ends of the photosensitive printing element with a filler material;
wherein a seamless photosensitive printing element is formable on the printing sleeve.

25. The apparatus according to claim 24, wherein the means for filling the gap comprises a spool valve that is capable of injecting molten filler material into the gap between the ends of the photosensitive printing element.
